(19) United States
(12) Patent Application Publication
(10) Pub. No.: US 2011/0265725 A1
(43) Pub. Date: Nov. 3, 2011

(54) FILM DEPOSITION DEVICE AND SUBSTRATE PROCESSING DEVICE

(75) Inventors: Norihiko Tsuji, Yamanashi (JP); Masayuki Moroi, Yamanashi (JP); Kenichi Yanagitani, Yamanashi (JP); Yoshiyuki Hanada, Yamanashi (JP)

(73) Assignee: TOKYO ELECTRON LIMITED, Tokyo (JP)

(21) Appl. No.: 13/120,681

(22) PCT Filed: Sep. 25, 2009
(86) PCT No.: PCT/JP2009/066607

§ 371 Date: May 31, 2011

(30) Foreign Application Priority Data
Sep. 26, 2008 (JP) 2008-248801

(51) Int. Cl. C23C 16/455; C23C 16/46; C23C 16/458

(52) U.S. Cl. 118/725

(57) ABSTRACT

A film deposition device includes a substrate transporting device arranged in a vacuum chamber to include a circulatory transport path in which substrate mounting parts arranged in a row are transported in a circulatory manner, the circulatory transport path including a linear transport path in which the substrate mounting parts are transported linearly. A first reactive gas supplying part is arranged along a transporting direction in which the substrate mounting parts are transported in the linear transport path, to supply a first reactive gas to the substrate mounting parts. A second reactive gas supplying part is arranged alternately with the first reactive gas supplying part along the transporting direction, to supply a second reactive gas to the substrate mounting parts. A separation gas supplying part is arranged to supply a separation gas to a space between the first reactive gas supplying part and the second reactive gas supplying part.

### TECHNICAL FIELD

The present disclosure relates to a film deposition device and a substrate processing device in which at least two mutually reactive gases are sequentially supplied to a surface of a substrate and the gas supplying cycle is repeated a number of times, so that a plurality of resultant layers are laminated on the substrate surface to form a thin film thereon.

### BACKGROUND ART

A film deposition process in a semiconductor fabrication process is known. In this process, a first reactive gas is supplied to a surface of a substrate, such as a semiconductor wafer W (wafer W), under a vacuum atmosphere. After the first reactive gas is adsorbed in the substrate surface, a second reactive gas is supplied to the substrate surface, and one or a plurality of atomic or molecular layers are formed by the reaction of these gases. By repeating the gas supplying cycle a number of times, these layers are laminated and a thin film is deposited on the substrate.

This process is called the ALD (Atomic Layer Deposition) process or the MLD (Molecular Layer Deposition) process. According to the number of gas supplying cycles, the thickness is controllable with good accuracy, and the homogeneity of the in-surface film is excellent. This process is a promising technique that provides the ability of the fabrication of thin-film semiconductor devices. For example, this process is appropriately applicable to the film deposition of Ru (ruthenium). When depositing a Ru film on the substrate, Ru(C₇H₇)(C₇H₁₁)(2,4-dimethylpentadienyl ethylcyclopentadienyl ruthenium) gas (DER gas) is used as the first reactive gas (source gas), and oxygen gas (O₂) is used as the second reactive gas (reducing gas).

As the device for carrying out the film deposition method described above, a sheet-type film deposition device provided with a gas shower head arranged in the center of the upper part of a vacuum chamber may be used. In such a device, reactive gases are supplied from the upper part of the central region of the substrate and the non-reacted reactive gases and secondary reaction products are exhausted from the bottom of a processing container.

In the case of the above film deposition method, much time is required for the gas replacement by the purge gas and the number of the gas supplying cycles amounts to hundreds of times. A long processing time is needed. And each time the film deposition of a substrate is processed, it is necessary to perform the delivery of the substrate into the processing container and the evacuation of the processing container. The time loss accompanying these operations is large. Hence, there is a demand for a device and method which are capable of performing the processing with high throughput.

In order to eliminate such problems, Patent Documents 1 and 2 listed below disclose the film deposition devices in which a plurality of substrates are placed on a circular mounting base in a circumferential direction, and one of reactive gases is selectively supplied to the substrates on the mounting base while the mounting base is rotated.

For example, in the film deposition device disclosed in the Patent Document 1, the composition in which a plurality of processing spaces are arranged in the circumferential direction of the mounting base and mutually different reactive gases are supplied to the processing spaces is proposed. In the film deposition device disclosed in the Patent Document 2, the composition in which two reaction gas nozzles are arranged above the mounting base and the different reactive gases are supplied to the mounting base is proposed. By rotating the mounting base, the substrates on the mounting base are allowed to pass through the plurality of processing spaces and the lower parts of the reaction gas nozzles, so that the film is deposited on each substrate by supplying the reactive gases to each substrate.

The film deposition device of the above type does not require the purge process of the reactive gases and can process the plurality of substrates by a single delivery operation and a single evacuation operation. The time loss accompanying these operations can be reduced and the throughput can be increased.

Patent Document 1: Japanese Patent No. 3,144,664 (FIGS. 1 and 2, claim 1)

### Patent Document 2: Japanese Laid-Open Patent Publication No. 2001-254181 (FIGS. 1 and 2)

### DISCLOSURE OF THE INVENTION

### Problem to be Solved by the Invention

However, in the case of the wafer W, the film deposition to the substrate whose diameter amounts to 300 mm is performed with enlargement of substrates in recent years. Therefore, the number of wafers W which can be laid on the common mounting base is limited and the number of wafers W which can be processed at a time is about 4-5 sheets. When the wafer W is delivered to the mounting base, the processing is suspended. If the delivery operation is needed each time 4-5 sheets of the wafers W are processed, the time for the delivery operation is accumulated in the whole film deposition processing. This may be an obstacle to improvement of the throughput.

When the mounting base is rotated, the moving speed of the center region differs from the moving speed of the peripheral region, and the moving speed of the peripheral region is larger than the moving speed of the center region. If the concentration of the reactive gas supplied from the reactive gas supplying nozzle in the diameter direction of the mounting base is constant, the amount of the reactive gases used for the film deposition on the wafer surface decreases as the moving speed of the wafer passing through the bottom of the reactive gas supplying nozzle increases.

For this reason, the amount of the reactive gas supplied from the nozzle is determined such that the concentration of the reactive gas which is sufficient for the film deposition on the wafer surface in the peripheral region of the mounting base where the moving speed passing through the lower part of the reactive gas supplying nozzle is higher may be obtained.

However, if the reactive gas is supplied in accordance with the required amount of the peripheral region of the mounting base in this way, the reactive gas of a concentration higher than the required amount will be supplied to the inner region of the mounting base whose moving speed is smaller than that of the peripheral region, and a certain amount of the reactive gas which is not used for the film deposition will be exhausted.

In order to improve the throughput, it is necessary to rotate the mounting base at a high speed. In such a case, the moving speed in the peripheral region of the mounting base becomes considerably high and the amount of reactive gas supplied must be increased. There is the problem that the amount of reactive gas which is not used for the film deposition but supplied may be increased.

Most of source gases used for the ALD process are obtained by evaporating a liquid material or sublimating a solid material, and the source gases are expensive. Such expensive reactive gases are consumed in the amount more than the amount required for the film deposition, for the purpose of improvement in the throughput of the wafer. It is desirable to provide a film deposition device which is able to reduce the reactive gas consumption and increase the throughput.

In one aspect, the present disclosure provides a film deposition device and a substrate processing device which are capable of reducing the consumption of reactive gases and raising the throughput.

### Means For Solving The Problem

In order to solve one or more of the above-described problems, the present disclosure provides a film deposition device in which at least two mutually reactive gases are sequentially supplied to a surface of a substrate in a vacuum chamber and the gas supplying cycle is repeated a number of times, so that a plurality of resultant layers are laminated on the substrate surface to form a thin film thereon, the film deposition device including: a substrate transporting device arranged in the vacuum chamber to include a circulatory transport path in which a plurality of substrate mounting parts arranged in a row are transported in a circulatory manner, the circulatory transport path including a linear transport path in which the plurality of substrate mounting parts are transported linearly; a first reactive gas supplying part arranged along a transporting direction in which the plurality of substrate mounting parts are transported in the linear transport path, to supply a first reactive gas to the plurality of substrate mounting parts which are transported in the linear transport path; a second reactive gas supplying part arranged alternately with the first reactive gas supplying part along the transporting direction, to supply a second reactive gas to the plurality of substrate mounting parts which are transported in the linear transport path; a separation gas supplying part arranged to supply a separation gas to a space between the first reactive gas supplying part and the second reactive gas supplying part, to separate a first region to which the first reactive gas is supplied from a second region to which the second reactive gas is supplied; an exhaust part arranged to exhaust the gases inside the vacuum chamber; a heating part arranged to heat a substrate on each of the plurality of substrate mounting parts; a substrate inlet part arranged on an upstream side of the linear transport path in the transporting direction so that a substrate is delivered by each of the plurality of the substrate mounting parts; and a substrate outlet part arranged on a downstream side of the linear transport path in the transporting direction so that a substrate from each of the plurality of substrate mounting parts is received through the substrate outlet part.

Moreover, in order to solve one or more of the above-described problems, the present disclosure provides a substrate processing device including: a vacuum transport chamber which contains a substrate transporting device inside the vacuum transport chamber; the above-mentioned film deposition device which is airtightly connected to the vacuum transport chamber; and a load lock chamber which is airtightly connected to the vacuum transport chamber and arranged so that the internal pressure of the load lock chamber is switchable between a vacuum pressure and an atmospheric pressure.

### BRIEF DESCRIPTION OF THE DRAWINGS

FIG. 1 is a plan view illustrating a substrate processing device of an embodiment of the present disclosure.

FIG. 2 is a perspective view illustrating the appearance of a film deposition device arranged in the substrate processing device.

FIG. 3 is a perspective view illustrating a substrate transporting device arranged in the film deposition device.

FIG. 4 is a diagram illustrating a part of the film deposition device.

FIG. 5 is a diagram illustrating a substrate mounting part and a substrate delivery unit of the film deposition device.

FIG. 6 is a plan view illustrating the substrate mounting part and the substrate delivery unit of the film deposition device.

FIG. 7 is a diagram illustrating the film deposition device.

FIG. 8 is a diagram illustrating a part of the film deposition device.

FIG. 9 is a cross-sectional view of the film deposition device taken along the line A-A′.

FIG. 10 is a diagram illustrating the arrangement of reaction gas nozzles and a separation gas nozzle of the film deposition device.

FIG. 11 is a perspective view illustrating a part of a partition plate of the film deposition device.

FIG. 12 is a diagram for explaining the partial pressures of reactive gases and a separation gas supplied from the reaction gas nozzles and the separation gas nozzle.

FIG. 13 is a plan view illustrating a part of the substrate processing device.

FIG. 14 is a plan view illustrating another embodiment of the present disclosure.

FIG. 15 is a plan view illustrating a part of another embodiment of the present disclosure.

FIG. 16 is a diagram illustrating a part of another embodiment of the present disclosure.

FIG. 17 is a plan view illustrating a part of another embodiment of the present disclosure.

### BEST MODE FOR CARRYING OUT THE INVENTION

In a film deposition device of one embodiment of the present disclosure, a plurality of mutually reactive gases are sequentially supplied to a surface of a substrate and the gas supplying cycle is repeated a number of times, so that a plurality of resultant layers are laminated on the substrate surface to form a thin film thereon by the repeated gas supplying cycle. The substrate is transported in accordance with a circulatory transport path including a linear transport path, and a first reactive gas and a second reactive gas are sequentially supplied to the substrate to perform the gas supplying cycle, film deposition processing can be performed with high throughput. Moreover, a plurality of substrate mounting parts arranged in a row are transported in accordance with the circulatory transport path, and the moving speed at the time of transport is constant in the surface of the substrate. Hence, it is not necessary to supply a large amount of reactive gas to the region in which the moving speed is low in accordance with the region in which the moving speed is high, and it is possible to prevent wasteful consumption of the reactive gas.

In the following, a description will be given of embodiments of the present disclosure with reference to the accompanying drawings.

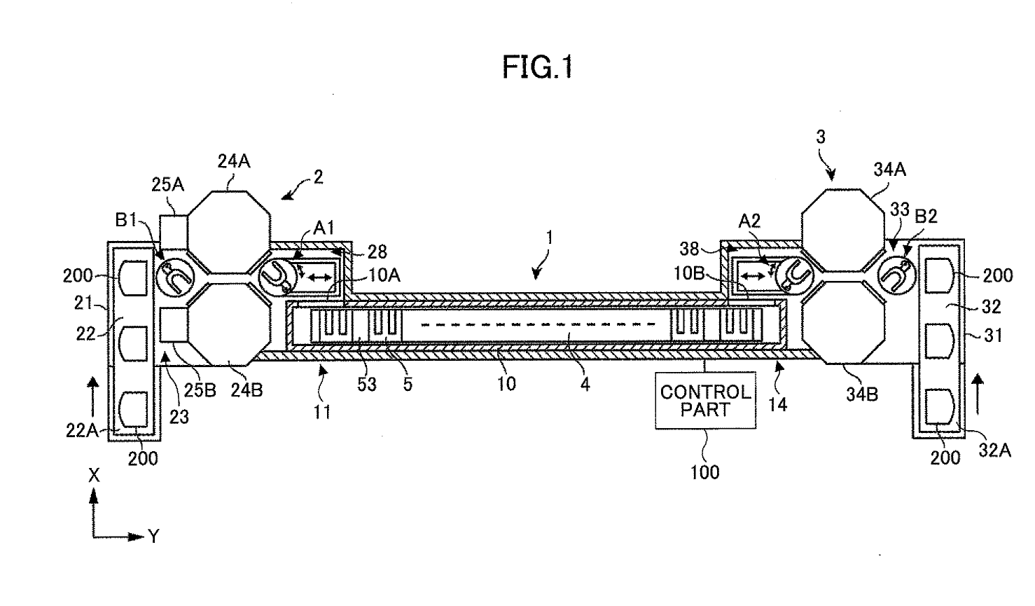

FIG. 1 is a plan view illustrating a substrate processing device of an embodiment of the present disclosure. The substrate processing device of this embodiment includes a film deposition device 1 which extends linearly in the Y direction in FIG. 1, and a substrate inlet region 2 for receiving the wafer W at the film deposition device 1 is arranged at one end of the film deposition device 1 in the longitudinal direction (the Y direction in FIG. 1), and a substrate delivery region 3 for delivering the wafer W from the film deposition device is arranged at the other end of the film deposition device 1 in the longitudinal direction.

A description will be given of the film deposition device 1 of this embodiment with reference to FIGS. 1-11. The film deposition device 1 includes a vacuum chamber 10 which is made of an aluminum alloy, and a substrate transporting device 4 is arranged inside the vacuum chamber 10. The substrate transporting device 4 is arranged so that a plurality of substrate mounting parts 5 arranged in a row in the transporting direction (the Y direction) in which the wafer W (the substrate) is mounted on each of the substrate mounting parts 5, and the plurality of substrate mounting parts 5 are transported in accordance with a circulatory transport path which includes a linear transport path.

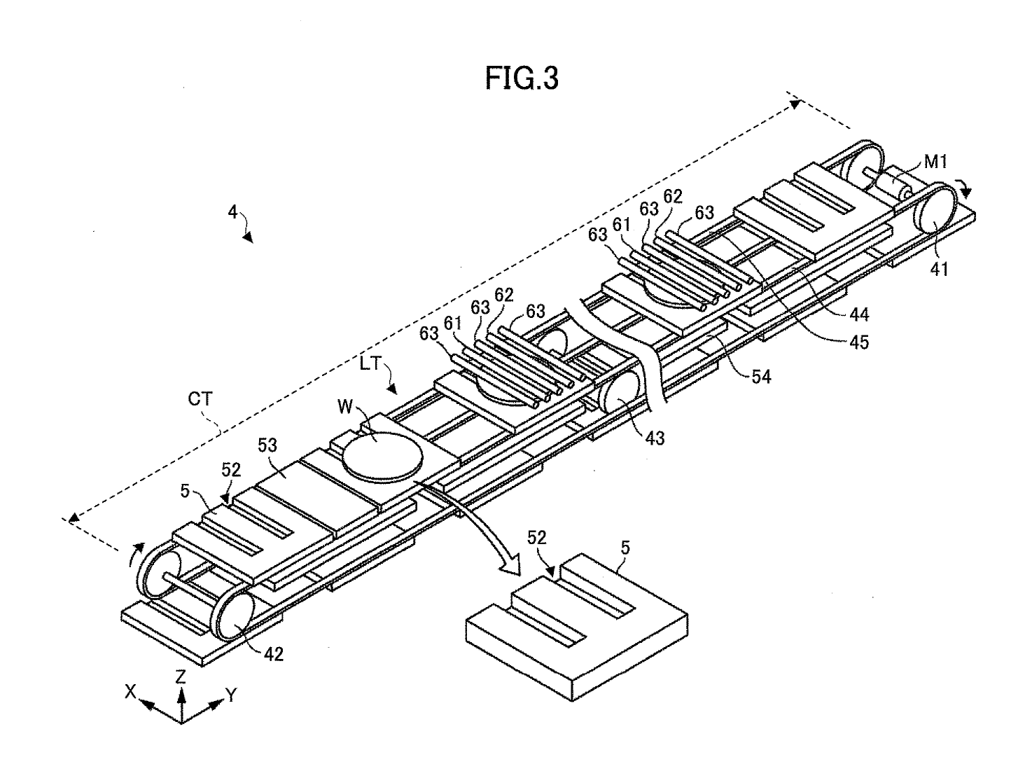

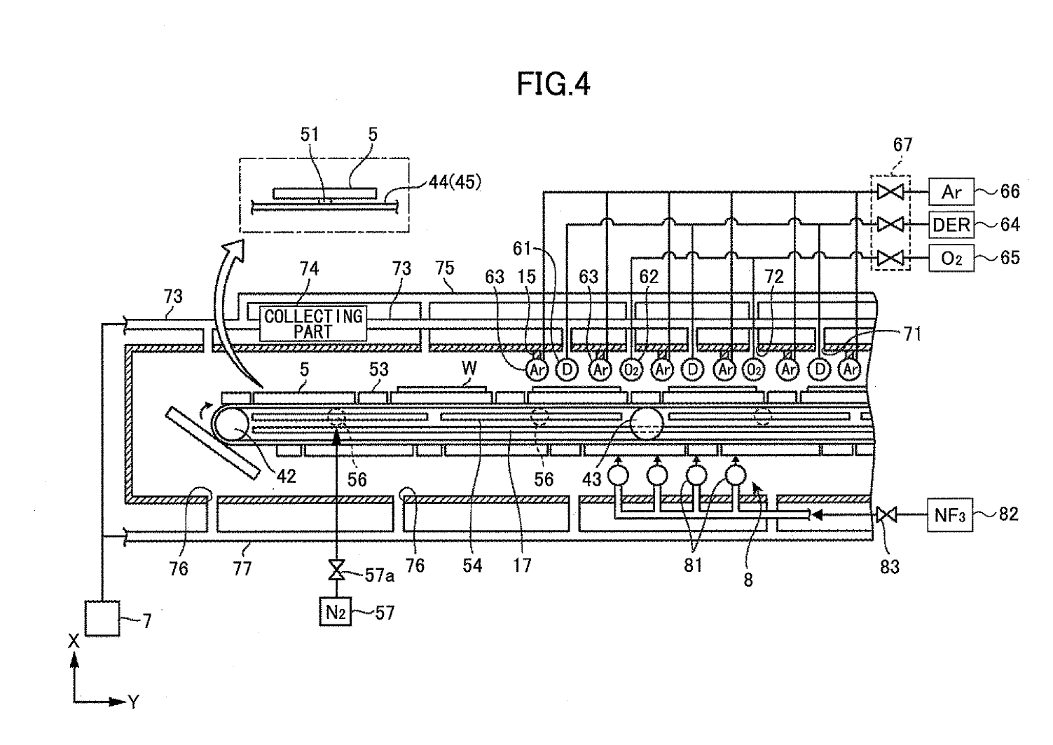

As illustrated in FIGS. 3 and 4, the substrate transporting device 4 includes the following elements. Pair of rotors 41 and 42 are arranged at front and rear ends of the substrate transporting device 4 so that the rotors are rotated around a horizontal axis and the rotating shafts of the rotors are parallel to each other. A pair of timing belts 44 and 45 (which are a pair of transmission belts) which are wound around the rotors 41 and 42 and moved in accordance with circulatory transport lines respectively. The rotor 41 constitutes a drive pulley rotated by a motor M1, and the rotor 42 constitutes a driven pulley. The drive of the drive pulley is controlled by a control part which will be described later.

In this example, one or more auxiliary belt pulleys 43 are arranged between the rotor (drive pulley) 41 and the rotor (driven pulley) 42. The timing belts 44 and 45 are wound around the rotors 41 and 42, respectively, and a circulatory transport path CT which goes around in a vertical direction is foamed. The circulatory transport path CT includes a linear transport path LT which extends linearly. Specifically, the circulatory transport path of this example includes upper and lower linear transport paths LT which confront each other. The circulatory transport path CT has a predetermined width (which is a length in the X direction).

The plurality of substrate mounting parts 5 are attached to the timing belts 44 and 45 such that the substrate mounting parts 5 are arranged in a row in the transporting direction. For example, each substrate mounting part 5 in this example has a flat, rectangular shape and has a size that a wafer W having a diameter of 300 mm may be mounted on the substrate mounting part 5.

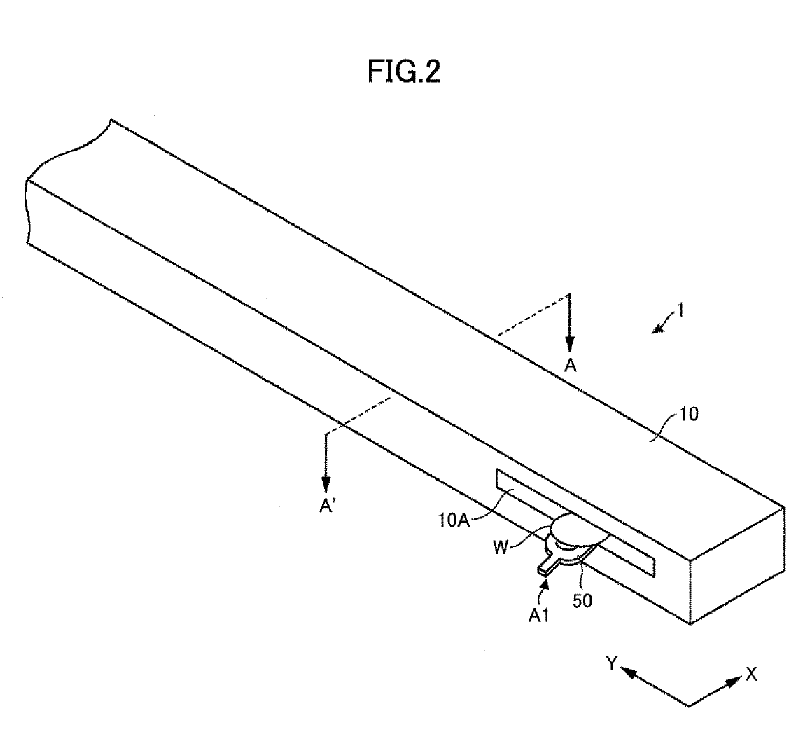

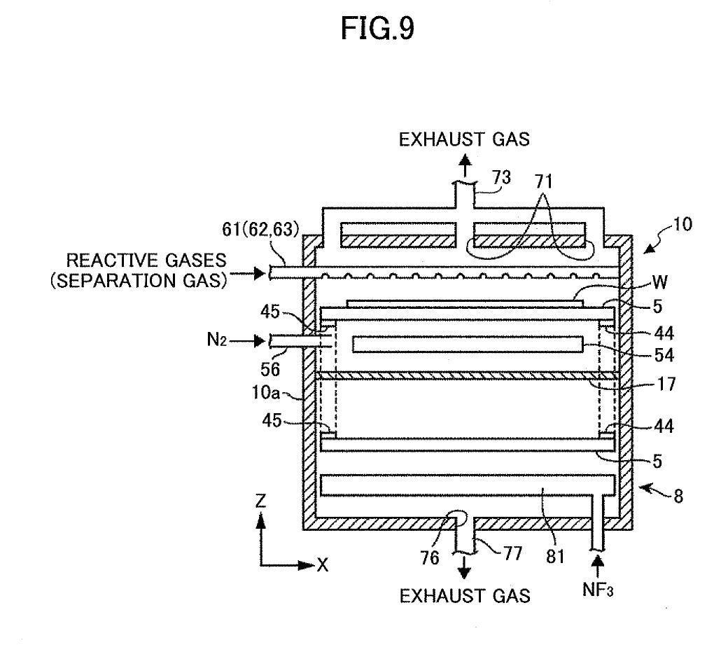

For example, each substrate mounting part 5 is arranged to bridge between the two timing belts 44 and 45. As illustrated in FIG. 3 and FIG. 9 (which is a cross-sectional view of the film deposition device taken along the line A-A′ in FIG. 2), the ends of each substrate mounting part 5 in the X direction in FIG. 3 are arranged to match the outer edges of the timing belts 44 and 45. Furthermore, as illustrated in FIG. 4, each substrate mounting part 5 is attached to the timing belts 44 and 45 via a fixing portion 51 arranged in the center of the timing belts 44 and 45 in the moving direction on the back surface of the substrate mounting part 5. For example, the fixing portion 51 may be formed of silicon carbide (SiC) or aluminum nitride (AlN). By this composition, when the circulatory movement of the timing belts 44 and 45 is performed by the rotors 41 and 42, the circulatory movement of the substrate mounting parts 5 is performed accordingly.

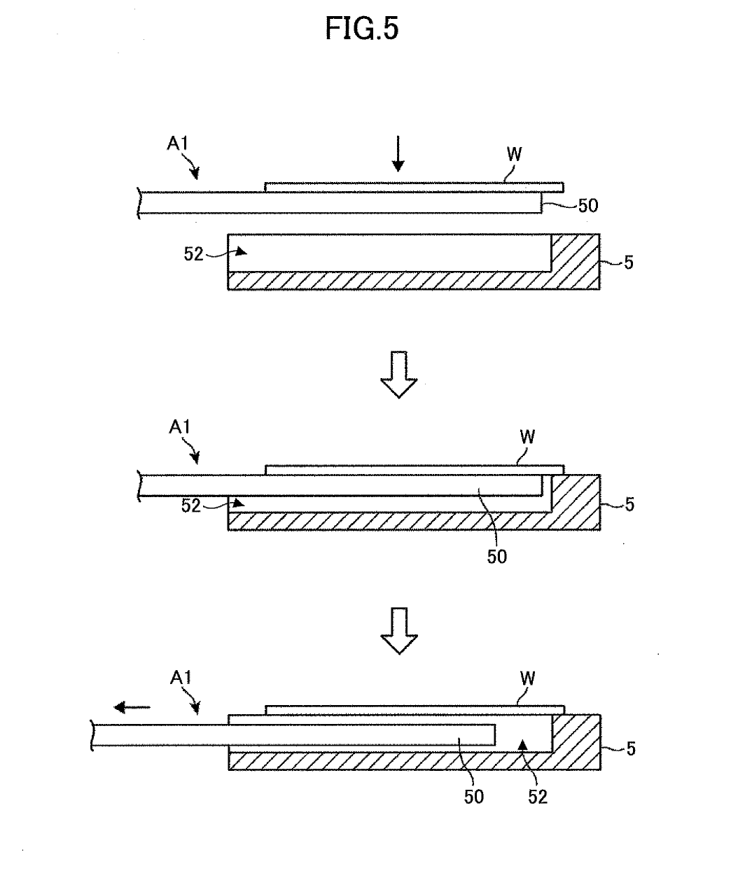

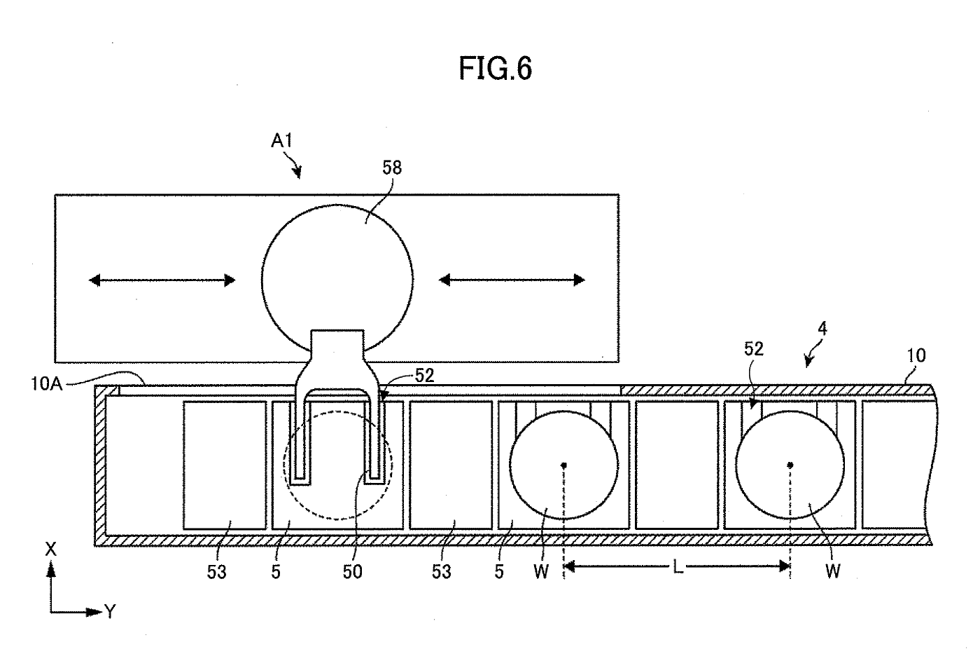

Step parts 52 are formed in each substrate mounting part 5, and the step parts 52 are used when the wafer W is delivered between the substrate mounting part 5 and the external substrate delivery unit A1 and when the wafer W is delivered between the substrate mounting part 5 and the substrate receiving unit A2. The substrate delivery unit Al and the substrate receiving unit A2 are arranged to have the same composition. The composition of the substrate delivery unit A1 will be described. As illustrated in FIGS. 2 and 6, the substrate delivery unit A1 is arranged to have a fork-shaped supporting plate 50 for supporting the back surface of the wafer W. As illustrated in FIG. 5, the size of the step parts 52 is larger than the size of the supporting plate 50. After the wafer W is held by the supporting plate 50, the supporting plate 50 enters the step parts 52 from the upper part of the step parts 52 to deliver the wafer W to the substrate mounting part 5. Then, the supporting plate 50 is returned back to the substrate delivery unit A1.

The plurality of substrate mounting parts 5 are arranged in a row in the transporting direction (the Y direction in FIG. 3) on the timing belts 44 and 45 at intervals of a predetermined distance between the adjacent substrate mounting parts 5. The distance of the intervals between the adjacent substrate mounting parts 5 may be determined by taking into consideration the transport speed of the substrate mounting parts 5 and the time needed for delivering the following wafer to the following substrate mounting part 5 after one wafer is delivered to one substrate mounting part 5 by the substrate delivery unit A1. For example, the distance of such intervals may be set up so that the distance L between the centers O of the adjacent wafers W as illustrated in FIG. 6 is equal to about 400 mm.

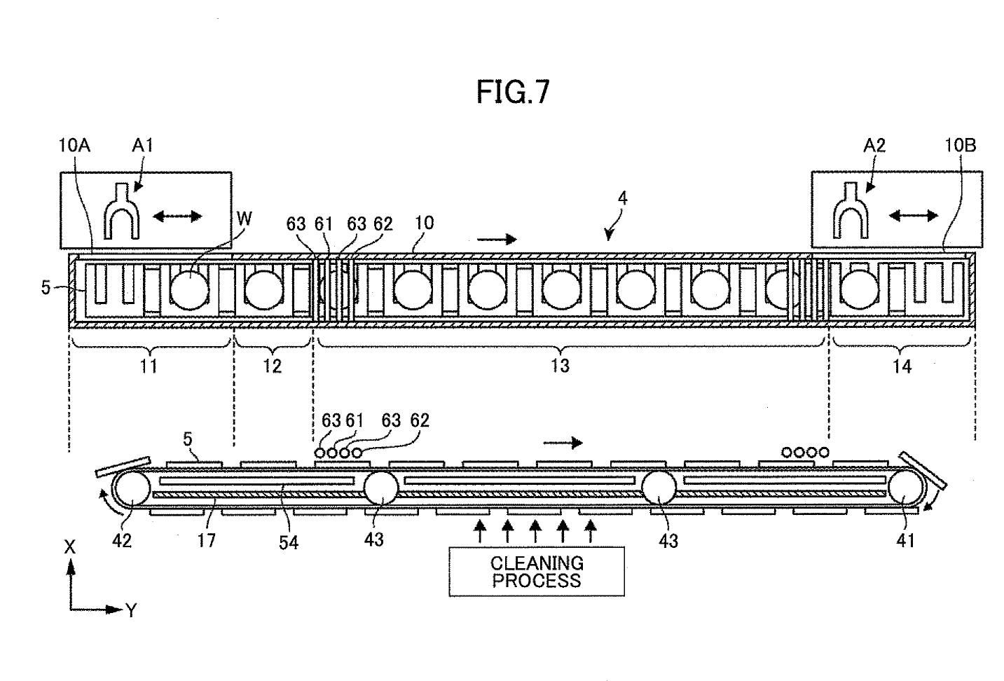

As illustrated in FIGS. 3 and 4, a spacer 53 is arranged between the adjacent substrate mounting parts 5. This spacer 53 is formed to have a shape and a size that fill the space between the adjacent substrate mounting parts 5 in the transporting direction adequately without interfering with the circulatory movement of the substrate mounting parts 5. In this example, the spacer 53 has a flat, rectangular shape. The spacer 53 has a width that is almost equal to the width of each substrate mounting part 5 (in the X direction), has a length in the Y direction that is slightly smaller than the distance between the adjacent substrate mounting parts 5 in the Y direction, and has a thickness that is almost equal to the thickness of each substrate mounting part 5. This spacer 53 is attached to the timing belts 44 and 45, similar to the substrate mounting parts 5, and the circulatory movement of the spacer 53 is performed together with the movement of the substrate mounting parts 5. For the sake of convenience, a single spacer 53 is illustrated in FIG. 3. Actually, two or more spacers 53 are arranged respectively between the adjacent ones of all the substrate mounting parts 5. In FIG. 7, the illustration of the spacer 53 is omitted.

As illustrated in FIG. 7, in the above-described substrate transporting device 4, a substrate inlet part 11 for receiving the wafer W at the substrate mounting part 5 is arranged at the upstream part of the linear transport path, and a substrate outlet part 14 for delivering the wafer W (which is subjected to the film deposition processing) from the substrate mounting part 5 is arranged at the downstream part of the linear transport path. A preheating region 12 and a processing region 13 are arranged between the substrate inlet part 11 and the substrate outlet part 14 sequentially from the substrate inlet part 11 side. In this way, by rotating the rotors 41 and 42, the substrate mounting parts 5 are moved from the substrate inlet part 11 to the substrate outlet part 14 through the preheating region 12 and the processing region 13, and subsequently the substrate mounting parts 5 are returned back to the substrate inlet part 11 through the circulatory movement of the substrate mounting parts 5.

A description will be given of the size of the vacuum chamber 10 and the size of the substrate transporting device 5. As illustrated in FIG. 6 and FIG. 9, the width (the length in the X direction) of the vacuum chamber 10 is slightly larger than the width of each substrate mounting part 5 such that each substrate mounting part 5 may be transported in a state in which the substrate mounting part 5 is in close proximity to the inner walls of the vacuum chamber 10. The respective lengths of the substrate inlet part 11, the preheating region 12, the processing region 13, and the substrate outlet part 14 in the Y direction (the transporting direction) are appropriately set up according to the transport speed of the substrate mounting parts 5, the kind of film deposition processing, etc. For example, the length of the processing region 13 in the transporting direction may be equal to about 5000 mm.

The film deposition device 1 is arranged to include a first reactive gas supplying part and a second reactive gas supplying part which are fixed in the vacuum chamber 10, such that the first reactive gas supplying part and the second reactive gas supplying part are arranged alternately along the linear transport path to supply the first reactive gas and the second reactive gas to the transport path of the substrate mounting part 5, respectively. The film deposition device 1 is further arranged to include a separation gas supplying part which is disposed between the first reactive gas supplying part and the second reactive gas supplying part to supply the separation gas to the transport path of the substrate mounting part 5 in order to separate the region to which the first reactive gas is supplied and the region to which the second reactive gas is supplied.

As illustrated in FIGS. 3 and 4, the first reactive gas supplying part, the second reactive gas supplying part, and the separation gas supplying part include a first reaction gas nozzle 61, a second reaction gas nozzle 62, and separation gas nozzles 63, respectively. These nozzles 61, 62, and 63 are disposed above the front surface of the substrate mounting part 5 in the processing region 13 in close proximity to the surface of the wafer W mounted on the substrate mounting part 5 to extend in a transverse direction perpendicular to the transporting direction of the linear transport path. In this example, the separation gas nozzle 63, the first reaction gas nozzle 61, the separation gas nozzle 63, the second reaction gas nozzle 62, and the separation gas nozzle 63 are arranged in this order in the direction from the substrate inlet part 11 toward the substrate outlet part 14, and the separation gas nozzles 63 are disposed at both the end portions of these gas nozzles. As illustrated in FIG. 9, these gas nozzles 61-63 are inserted into the vacuum chamber 10 through the side wall part 10a of the vacuum chamber 10, the leading end of each gas nozzle is arranged in contact with the side wall part 10b which faces the side wall part 10a through which the gas nozzles 61-63 are inserted.

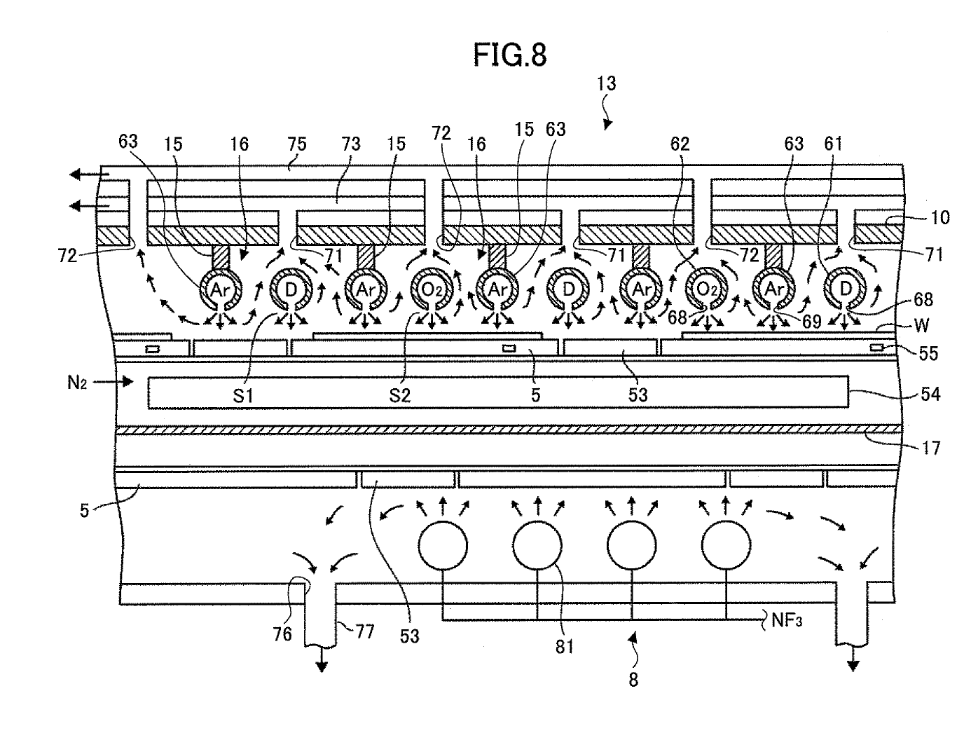

As illustrated in FIG. 8, the partitioning wall 15 is arranged between the upper part of each separation gas nozzle 63 and the ceiling part of the vacuum chamber 10. The partitioning wall 15 fully extends in the longitudinal direction of the separation gas nozzle 63 (the X direction), and the region 16 defined by the partitioning walls 15 is formed between the adjacent separation gas nozzles 63 in the upper part above the gas nozzles in the vacuum chamber 10.

The first reaction gas nozzles 61 are connected to the gas supply source 64 of DER gas which is the first reactive gas. The second reaction gas nozzles 62 are connected to the gas supply source 65 of O₂ gas (oxygen gas) which is the second reactive gas, and the separation gas nozzles 63 are connected to the gas supply source 66 of Ar gas (argon gas) which is the separation gas. Other examples of the separation gas which may be used instead of Ar gas include nitrogen (N2) gas, helium (helium) gas, etc. In FIG. 4, reference numeral 67 denotes a flow rate adjustment part.

As illustrated in FIGS. 8 and 9, discharge holes 68 for discharging the reactive gas downward are formed in the reaction gas nozzles 61 and 62 at intervals in the longitudinal direction of the reaction gas nozzles 61 and 62 (the X direction). As illustrated in FIGS. 8 and 9, discharge holes 69 for discharging the separation gas downward are formed in the separation gas nozzles 63 at intervals in the longitudinal direction of the separation gas nozzles 63. The lower part regions of the reaction gas nozzles 61 and 62 constitute the first region S1 for making DER gas stick to the wafer W and the second region S2 for making O₂ gas stick to the wafer W, respectively. The separation gas nozzles 63 are disposed between the first region S1 and the second region S2 to separate the first region S1 and the second region S2 from each other.

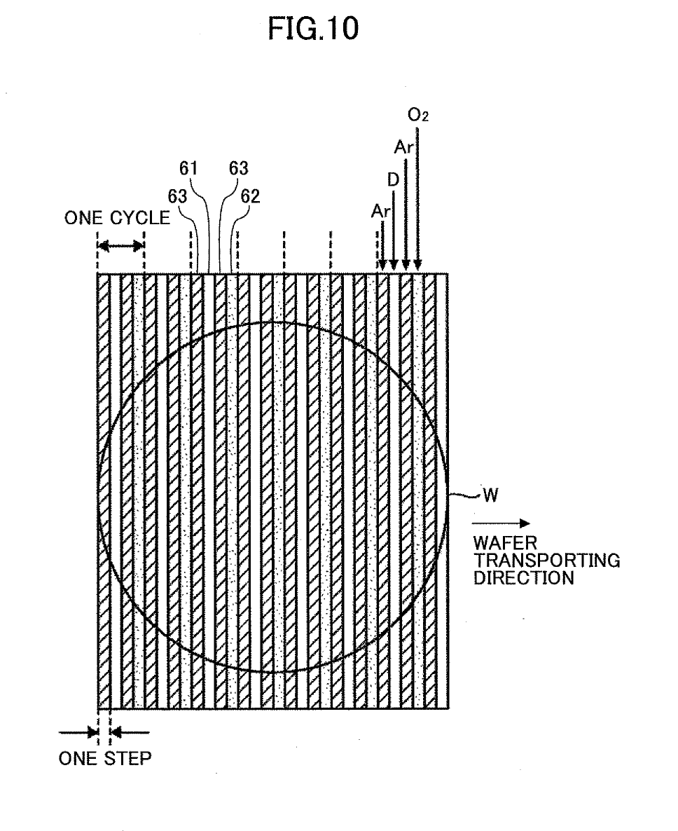

As illustrated in FIG. 10, each of the reaction gas nozzles 61 and 62 and the separation gas nozzles 63 has a region (one step) where the wafer W is exposed to one gas which is 10 mm long in the wafer transporting direction. For example, these nozzles are arranged so that the total region of the wafer W which is exposed in one cycle to Ar gas, DER gas, Ar gas, and O₂ gas sequentially in this order has a length of 40 mm in the wafer transporting direction.

The vacuum chamber 10 includes the exhaust ports which are formed to exhaust the gas from the spaces between the adjacent separation gas supply regions. Each exhaust port is formed in the ceiling part of the vacuum chamber 10 as illustrated in FIG. 4, FIG. 8 and FIG. 9.

The partitioning wall 15 is arranged between the separation gas nozzle 63 and the ceiling part of the vacuum chamber 10. By the partitioning walls 15, the region in which the first reaction gas nozzle 61 is formed and the region in which the second reaction gas nozzle 62 is formed are divided at the upper part of the gas nozzles 61-63. Therefore, by forming the first exhaust ports 71 which are open to the arrangement regions of the first reaction gas nozzles 61, and by forming the second exhaust ports 72 which are open to the arrangement regions of the second reaction gas nozzles 62, the first reactive gas is exhausted from the first exhaust ports 71, and the second reactive gas is exhausted from the second exhaust ports 72.

Referring to FIG. 4, the first exhaust port 71 is connected to the first exhaust path 73, and connected to the vacuum pump 7 via the collecting part 74. The collecting part 74 is arranged to collect the DER gas which is the first reactive gas. For example, the collecting part 74 is arranged to collect the DER gas from the exhaust gas by cooling. The second exhaust port 72 is connected to the second exhaust path 75, and the second exhaust path 75 is connected to the first exhaust path 73 in the downstream position of the collecting part 74, and connected to the vacuum pump 7. Furthermore, one or more exhaust ports 76 are arranged also in the bottom of the vacuum chamber 10. These exhaust ports 76 are connected to the third exhaust path 77, connected to the first exhaust path 73, and connected to the vacuum pump 7.

As illustrated in FIGS. 3 and 4, a heater unit 54 (which is a heating part) is formed in the region of the substrate transporting device 4 surrounded by the circulatory transport path along the longitudinal direction of the substrate transporting device 4 (the Y direction), and the wafer W is heated through the substrate mounting part 5 by the radiation heat from the heater part 54. A temperature sensor 55 (refer to FIG. 8) which is consisted of a radiation thermometer is arranged in the substrate mounting part 5, and the wafer W is heated by the heater unit 54 to a temperature which is determined according to the process specification based on the detection temperature output from the temperature sensor 55.

In this example, a plurality of heater units 54 which have a size which can heat the whole surface of the substrate mounting part 5 is arranged in the X direction and the Y direction fully in the whole longitudinal direction of the circulatory transport path (the transporting direction) except for the regions where the rotors 41 and 42 are arranged. The wafer W delivered from the substrate inlet part 11 to the substrate mounting part 5 is heated simultaneously with the transport. The preheating region 12 for preheating the wafer is arranged between the substrate inlet part 11 in the circulatory transport path and the processing region 13 to which the reactive gas is supplied, and the wafer is fully heated while the wafer is transported in the preheating region 12. The degree of heating of the wafer W varies depending on the time for the wafer W to pass through the preheating region 12, and the size of the preheating region 12 (the length in the transporting direction) may be determined according to the transport speed or the kind of film deposition processing.

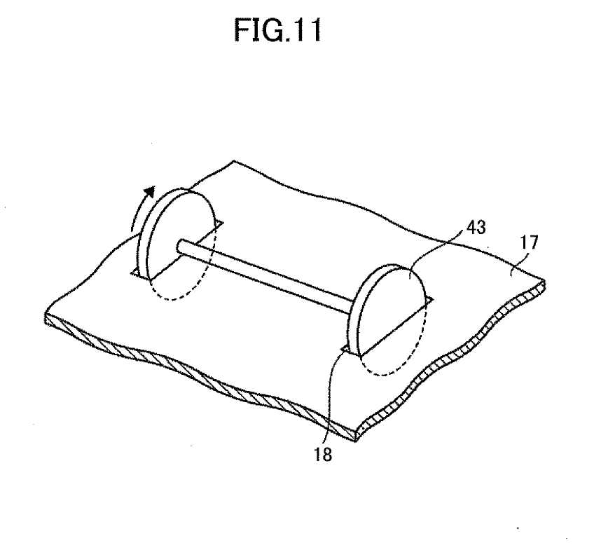

As illustrated in FIGS. 4, 8, and 9, a partition plate 17 is disposed at the lower part side of the heater unit 54 in the region of the substrate transporting device 4 surrounded by the circulatory transport path. The partition plate 17 is formed to divide perpendicularly the vacuum chamber 10 in the region between the drive pulley 41 and the driven pulley 42 into two halves. As illustrated in FIG. 11, notches 18 are formed in the partition plate 17 in the movement region of the auxiliary belt pulley 43 so that rotation of the auxiliary belt pulley 43 may not be prevented by the partition plate 17.

As illustrated in FIGS. 4 and 9, a purge gas nozzle 56 for supplying N₂ gas (which is the purge gas) to the space between the substrate mounting part 5 and the partition plate 17 is further formed in the vacuum chamber 10. The purge gas nozzle 56 is arranged so as not to prevent the circulatory movement of the substrate mounting part 5, and one end of the purge gas nozzle 56 is connected to the purge gas source 57 (FIG. 4) via the flow rate adjustment part 57a. Other examples of the purge gas which may be used instead of N₂ gas include Ar gas, helium gas, etc.

Moreover, in the vacuum chamber 10, a cleaning process part 8 for performing a cleaning process of the substrate mounting part 5 during movement in the linear transport path is disposed at the lower part of the substrate transporting device 4. The cleaning process part 8 is arranged to supply the cleaning gas to the substrate mounting part 5 and perform the cleaning process, while the substrate mounting part 5 delivers the wafer W in the substrate outlet part 14 to the substrate receiving unit A2 in the substrate transporting device 4 and is returned from the substrate outlet part 14 to the substrate inlet part 11.

For example, as illustrated in FIGS. 4 and 8, the cleaning process part 8 includes a plurality of plasma generating parts 81 in the vacuum chamber 10, each of which extends in a direction perpendicular to the transporting direction. The size, the shape, the number, the fixing position, etc. of the plasma generating parts 81 are set up to supply the cleaning gas to the whole substrate mounting part 5 which is transported. NF₃ gas which is the cleaning gas is supplied to the plasma generating part 81 from the supply source 82 of NF₃ gas, and the substrate mounting part 5 is exposed to NF₃ gas in a plasma state generated from the plasma generating part 81, so that the substrate mounting part 5 is cleaned. In FIG. 4, reference numeral 83 denotes a flow rate adjustment part.

In this example, the exhaust ports 76 on the bottom of the vacuum chamber 10 are formed before and behind the plasma generating parts 81 in the transporting direction, and the cleaning gas is promptly exhausted via the exhaust ports 76. The cleaning gas may be appropriately chosen according to the kind of film deposition processing.

The flow rate adjustment parts 67 which control the flow rates of the first reactive gas, the second reactive gas, and the separation gas, the flow rate adjustment part 57a which adjusts the flow rate of the purge gas, and the flow rate adjustment part 83 which controls the flow rate of the cleaning gas are controlled by a control part 100 which will be described later, and each of the gases at a predetermined flow rate is supplied in the vacuum chamber 10 at a predetermined timing respectively.

In this example, the cleaning gas in the plasma state is supplied by the cleaning process part 8. However, the use of the cleaning gas in the plasma state is not mandatory. Alternatively, for example, ClF₃ gas may be used as the cleaning gas and the cleaning process of the substrate mounting part 5 may be performed by supplying this gas to the substrate mounting part 5 directly.

Next, the substrate inlet part 11 and the substrate outlet part 14 will be described.

In this embodiment, the wafer W is delivered to the substrate mounting part 5 in the substrate inlet part 11 by the substrate delivery unit A1, and the wafer W from the substrate mounting part 5 in the substrate outlet part 14 is received by the external substrate receiving unit A2.

As illustrated in FIGS. 1 and 2, the vacuum chamber 10 is arranged to include a delivery opening 10A formed in the side wall part of the vacuum chamber 10 in the substrate inlet part 11, and a receiving opening 10B is formed in the side wall part of the vacuum chamber 10 in the substrate outlet part 14. The delivery opening 10A and the receiving opening 10B are opened or closed by the gate valves which are not illustrated.

The substrate delivery unit A1 is disposed in the outside of the delivery opening 10A in the vacuum chamber 10, and the substrate receiving unit A2 is disposed in the outside of the receiving opening 10B. The substrate delivery unit A1 and the substrate receiving unit A2 are arranged to have the same composition.

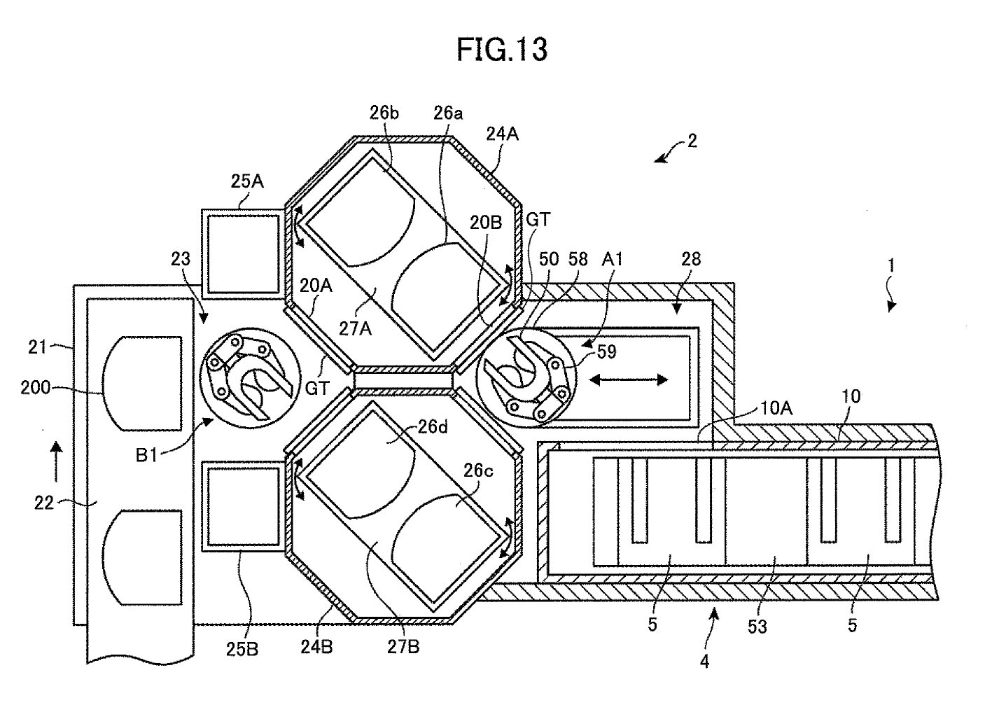

Next, the substrate receiving unit A1 will be described. As illustrated in FIGS. 6 and 13, the substrate delivery unit A1 includes a base 58 and a multi-joint arm 59. The base 58 is arranged to be vertically movable, horizontally rotatable, and horizontally movable in the transporting direction (the Y direction). The multi-joint arm 59 is arranged on the base 58 to be transversely movable. The head of the multi-joint arm 59 is arranged as a supporting plate 50 in the shape of a fork which supports the back surface of the wafer W. The illustration of the multi-joint arm 59 is omitted in FIG. 6. The base 58 can be moved in the transporting direction in parallel to the circulatory transport path in the vacuum chamber 10.

The substrate delivery unit A1, the substrate receiving unit A2, and the substrate transporting device 4 are controlled by the control part 100 (which will be described later) in the following manner. The substrate delivery unit A1 delivers the wafer W to the substrate mounting part 5 in the state where the substrate mounting part 5 is moving in the substrate inlet part 11. The substrate receiving unit A2 receives the wafer W from the substrate mounting part 5 in the state where the substrate mounting part 5 is moving in the substrate outlet part 14. A control signal is output from the control part 100 to each of the substrate delivery unit A1, the substrate receiving unit A2, and the substrate transporting device 4, so that the substrate delivery unit A1, the substrate receiving unit A2, and the substrate transporting device 4 are controlled by the control part 100.

Thus, the wafer W is delivered to the substrate mounting part 5 or the wafer W is received from the substrate mounting part 5 when the substrate mounting part 5 is moving in the transporting direction. The substrate inlet part 11 provides the region which the substrate delivery unit A1 can access, and the substrate outlet part 14 provides the region which the substrate receiving unit A2 can access. The length of each of the substrate inlet part 11 and the substrate outlet part 14 in the transporting direction is determined by taking into consideration the transport speed of the substrate mounting part 5.

Next, the substrate inlet region 2 will be described with reference to FIGS. 1 and 13. In FIGS. 1 and 13, reference numeral 21 denotes a Foup mounting part for mounting the plural Foups 200 in which many wafers W from the exterior are accommodated. The Foup mounting part 21 includes an installation stage 22 which is arranged to be movable in the X direction. For example, an inlet opening 22A of the Foup 200 is formed in the upstream position of the installation stage 22 in the X direction. The Foup 200 is mounted on the installation stage 22 and moved from the inlet opening 22A downstream in the X direction.

Two load lock chambers 24 (24A, 24B) are connected to the Foup mounting part 21 via the air transport chamber 23 in which the air atmosphere is formed. A first delivery arm B1 for delivering the wafer W between the Foup 200 mounted on the Foup mounting part 21 and the load lock chambers 24A and 24B is disposed in the air transport chamber 23. The first delivery arm B1 in this example is arranged so that the arm can access the Foup 200 placed on the installation stage 22 at the furthest downstream position in the moving direction and the load lock chambers 24A and 24B. In order to deliver the wafer W in the Foup 200 to the load lock chambers 24A and 24B, the first delivery arm B1 is arranged to be vertically movable, horizontally rotatable around a vertical rotating shaft, and transversely movable.

The alignment units 25A and 25B for performing alignment of the wafer W are disposed in the air transport chamber 23, and the delivery arm B1 is arranged to access the alignment units 25A and 25B.

The load lock chambers 24A and 24B are arranged to have the same composition. The internal pressure of each of the load lock chambers 24A and 24B is switchable between a normal pressure and a vacuum pressure. As illustrated in FIG. 13, a pair of buffers 26a and 26b (26c, 26d) for holding the wafers W in the stacked state are arranged inside each of the load lock chambers 24A and 24B. These buffers 26a and 26b (26c, 26d) are mounted on the rotating stage 27A (27B) which are rotatable around a vertical axis.

The load lock chambers 24A and 24B are connected to the vacuum transport chamber 28 containing the vacuum atmosphere, and the wafer W are received in the vacuum transport chamber 28 from the buffers 26a and 26b (26c, 26d) in the load lock chambers 24A and 24B, and the substrate delivery unit A1 for delivering the wafer W to the film deposition device 1 is arranged for this purpose.

The first opening 20A is formed between the air transport chamber 23 and each of the load lock chambers 24A and 24B, and the second opening 20B is formed between each of the load lock chambers 24A and 24B and the vacuum transport chamber 28.

The gate valve GT which can be opened or closed by the control part is arranged at each of the openings 20A and 20B to provide airtight sealing of the opening, respectively. The first opening 20A and the second opening 20B are arranged in the positions which the first delivery arm B1 and the substrate delivery unit A1 can access respectively. By rotating the stages 27A and 27B inside the load lock chambers 24A and 24B, a corresponding one of the buffers 26a-26d is moved to the position facing the first opening 20A and the wafer is delivered to the corresponding one of the buffers 26a-26d by the first delivery arm B1. By rotating the stages 27A and 27B inside the load lock chambers 24A and 24B, a corresponding one of the buffers 26a-26d is moved to the position facing the second opening 20B and the wafer W from the corresponding one of the buffers 26a-26d is received by the substrate delivery unit A1.

On the other hand, the substrate delivery region 3 (FIG. 1) is arranged similar to the substrate inlet region 2. In FIG. 1, reference numeral 31 denotes a Foup mounting part for mounting the plural Foups 200, reference numeral 32 denotes a delivery installation stage, and reference numeral 32A denotes a delivery opening of the Foup 200. In FIG. 1, reference numeral 33 denotes an air transport chamber containing the air atmosphere, and reference numerals 34A and 34B denote two load lock chambers. The second delivery arm B2 is arranged in the air transport chamber 33. The buffers (not illustrated) are mounted on the rotating stage and arranged in the inside of the load lock chambers 34A and 34B.

The load lock chambers 34A and 34B are connected to the vacuum transport chamber 38 containing the vacuum atmosphere, and the substrate receiving unit A2 is disposed in the vacuum transport chamber 38 to receive the wafer W from the film deposition device 1 and to deliver the wafer W to the buffers in the load lock chamber 34A and 34B.

In the film deposition device of this embodiment, the control part 100 which includes a microcomputer for controlling operation of the whole film deposition device 1 is arranged. The program for operating the film deposition device 1 is stored in the memory of the control part 100. The program is constructed from a set of code instructions for performing the operation of the film deposition device (which will be described later), read from a storage medium, such as a hard disk, a compact disc, a flash memory, a memory card, or a flexible disk, and installed in the control part 100.

Next, operation of the above-described embodiment will be described. The lid in the Foup 200 mounted on the Foup mounting part 21 is opened by the opening/closing device (not illustrated), and the wafer W is received from the inside of the Foup 200 by the first delivery arm B1 in the air transport chamber 23. Positioning of the wafer W is performed by the alignment unit 25A or 25B, and the wafer W is delivered to the buffers 26a-26d of the load lock chambers 24A and 24B.

Subsequently, the inside of the load lock chamber 24A and 24B is changed from the air to the vacuum. Subsequently, the gate valve GT is opened and the wafer W in the load lock chambers 24A and 24B is received through the opening 20B by the substrate delivery unit A1 in the vacuum transport chamber 28.

On the other hand, in the film deposition device 1, the inside of the vacuum chamber 10 is maintained beforehand at a predetermined vacuum pressure by the vacuum pump 7 (FIG. 4). While the temperature of the substrate mounting part 5 is measured by the temperature sensor 55, the substrate mounting part 5 is heated beforehand to about 300 degrees C. by the heater unit 54, and the circulatory movement of the substrate transporting device 4 in the transporting direction (the Y direction in FIG. 5) is performed at a moving speed of about 50 mm/sec.

The substrate delivery unit A1 delivers the wafer W to the substrate mounting part 5, while the substrate delivery unit A1 is moved in the same direction at the moving speed that is the same as the moving speed of the substrate transporting device 4.

Subsequently, the substrate delivery unit A1 promptly receives the following wafer W to the load lock chambers 24A and 24B, and delivers the wafer W to the following substrate mounting part 5 in a similar manner. As described previously, the substrate mounting parts 5 are arranged so that the gap L between the wafers W in the transporting direction may be set to about 400 mm, and the time for the receiving of the wafer W is about 8 seconds.

In this way, the wafer W is transported from the substrate inlet part 11 to the preheating region 12 in the state where the wafer W is mounted on the substrate mounting part 5, and while the wafer W is moved in the preheating region 12, the wafer W is heated to a predetermined temperature by the substrate mounting part 5.

Subsequently, the wafer W is moved to the processing region 13. In the processing region 13, DER gas and O₂ gas are supplied respectively from the first reaction gas nozzle 61 and the second reaction gas nozzle 62, and Ar gas (which is the separation gas) is supplied from the separation gas nozzle 63. N2 gas (which is the purge gas) is supplied to the inside of the circulatory transport path of the substrate transporting device 4 from the purge gas nozzle 56. At this time, the flow rate of each gas is set up so that the pressure inside the circulatory transport path is set to a positive pressure slightly higher than the pressure of the exterior of the circulatory transport path.

The wafer W is moved in the transporting direction (the Y direction) by the substrate transporting device 4, and the wafer W is passed through the first region S1 in which the first reaction gas nozzle 61 is formed, and the second region S2 in which the second reaction gas nozzle 62 is formed alternately.

That is, DER gas is adsorbed by the surface of the wafer W first, and subsequently O₂ gas is adsorbed by the surface of the wafer W, so that reduction reaction of the DER gas takes place and one or a plurality of Ru molecular layers are formed on the wafer W.

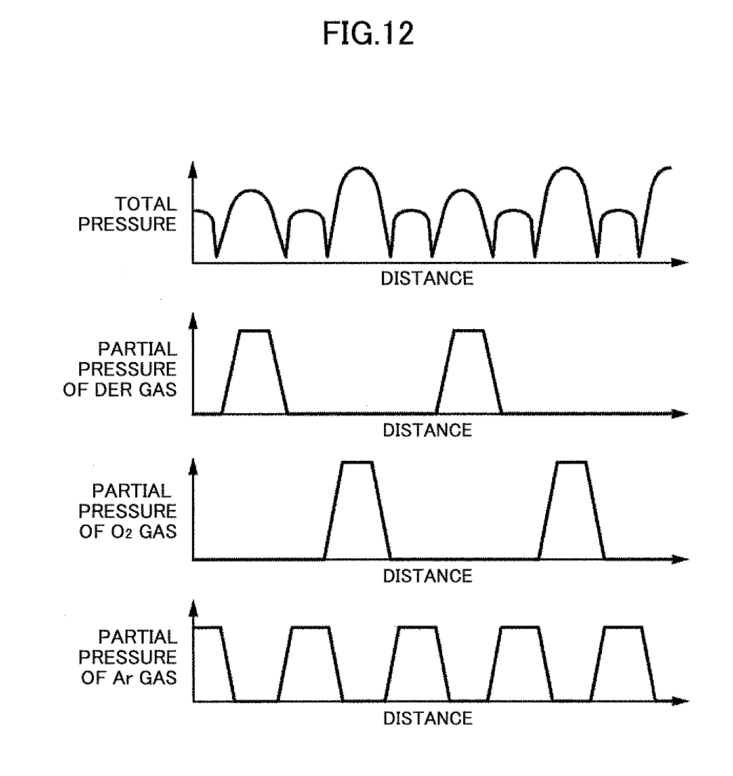

Subsequently, the wafer W passes through the first region S1 and the second region S2 alternately, and a Ru film which includes the Ru molecular layers laminated and has a predetermined thickness is formed. FIG. 12 illustrates the relationship between the partial pressures of the DER gas, the O₂ gas, and the Ar gas and the distance traveled in the transporting direction at this time. In this manner, Ar gas, DER gas, Ar gas, O₂ gas, and Ar gas are supplied in this order to the wafer W alternately.

The gas flow in the vacuum chamber 10 will be described with reference to FIG. 8. In the processing region 13, the separation gas nozzle 63, the first reaction gas nozzle 61, the second reaction gas nozzle 62, and the separation gas nozzle 63 are arranged in this order along the transporting direction of the wafer W. As previously described, the partitioning wall 15 is arranged between the separation gas nozzle 63 and the ceiling part of the vacuum chamber 10, and the reaction gas nozzles 61 and 62 are arranged in the spaces 16 between the separation gas nozzles 63 respectively. The first exhaust ports 71 and the second exhaust ports 72 are arranged above the reaction gas nozzles 61 and 62 in the spaces 16 respectively, and the gas in each space 16 is exhausted from the upper part. From the first exhaust ports 71, the DER gas (which is the first reactive gas) and the separation gas are exhausted. When these gases pass the collecting part 74 arranged in the first exhaust path 73, the DER gas is collected by the collecting part 74.

DER gas supplied to the wafer W on the substrate mounting part 5 from the first reaction gas nozzle 61 is adsorbed by the wafer W, and DER gas which is not adsorbed is exhausted from the first exhaust ports 71 arranged in the spaces 16.

The substrate mounting part 5 is transported in close proximity with the inner wall of the vacuum chamber 10, and a narrow gap between the substrate mounting part 5 and the vacuum chamber 10 is provided in the linear transport path. The spacer 53 is formed between the adjacent substrate mounting parts 5 and a narrow gap between the substrate mounting part 5 and the spacer 53 is provided. That is, there are very narrow gaps in the region in which the linear transport path is arranged. Therefore, downward flow of the DER gas supplied from the first reaction gas nozzle 61 is prevented by the substrate mounting part 5 and the spacer 53, and upward flow of the DER gas is allowed and the DER gas is exhausted from the first exhaust ports 71.

On the other hand, O₂ gas supplied to the wafer W on the substrate mounting part 5 from the second reaction gas nozzle 62 is adsorbed by the wafer W, and O₂ gas which is not adsorbed is exhausted from the second exhaust ports 72 arranged in the spaces 16 defined by the partitioning walls 15. In this case, downward flow of the O₂ gas is prevented by the substrate mounting part 5 and the spacer 53, the O₂ gas flows towards the upper part and is exhausted from the second exhaust ports 72.

The separation gas nozzles 63 are formed on the both sides of the first reaction gas nozzle 61 and the second reaction gas nozzle 62, and Ar gas is supplied from the separation gas nozzles 63. The Ar gas supplied from the separation gas nozzles 63 on the both sides also flows towards the substrate mounting part 5. Downward flow of the Ar gas is prevented by the substrate mounting part 5 and the spacer 53, and the Ar gas flows upward and is exhausted from the first exhaust ports 71 and the second exhaust ports 72 which are open to the spaces 16. Thus, the Ar gas which is the separation gas is supplied between the DER gas which is the first reactive gas and the O₂ gas which is the second reactive gas. The first region S1 to which the first reactive gas (DER) is supplied and the second region S2 to which the second reactive gas (O₂) is supplied are separated from each other, and mixing of these gases (in the vacuum chamber) before the gases are supplied to the wafer W is prevented.

In this way, while the DER gas and the O₂ gas are alternately adsorbed by the surface of the wafer W, the wafer W is moved to the processing region 13 in the transporting direction, and the wafer W in the substrate outlet part 14 is sequentially received by the substrate receiving unit A2 through the operation which is reverse to the substrate inlet operation. The wafer W received from the film deposition device 1 is delivered to the load lock chambers 34A and 34B by the substrate receiving unit A2, and the wafer W is held by the delivery arm B2 and delivered to the corresponding Foup 200.

On the other hand, the substrate transporting device 4 continuously performs the circulatory movement, and the substrate mounting part 5 in which the wafer W in the substrate outlet part 14 is received by the substrate receiving unit A2 is moved to the lower part of the circulatory transport path. The substrate mounting part 5 is exposed to the cleaning gas (NF3 gas) in the plasma state in the cleaning process part 8 so that the predetermined cleaning process is performed, while the substrate mounting part 5 is returned from the substrate outlet part 14 to the substrate inlet part 11. By this cleaning process, the resultant which is produced by the reaction of DER and O₂ and adheres to the substrate mounting part 5 is removed.

In the cleaning process, the cleaning gas is supplied from the lower part to the substrate transporting device 4, and the upward flow of this cleaning gas is prevented by the substrate mounting part 5 and the spacer 53, and the cleaning gas flows towards the lower part again and is exhausted via the exhaust ports 76 which are open to the bottom of the vacuum chamber 10.

Because the partition plate 17 is formed in the inside of the circulatory transport path in the substrate transporting device 4, even if the reactive gas and the separation gas from the upper part of the substrate transporting device 4 enter the lower part of the substrate mounting part 5 via the gap between the substrate mounting part 5 and the spacer 53, further downward flow of such gases is prevented by the partition plate 17.

On the other hand, even if the cleaning gas from the lower part of the substrate transporting device 4 enters the upper part of the substrate mounting part 5 via the gap between the substrate mounting part 5 and the spacer 53, further upward flow of the cleaning gas is prevented by the partition plate 17. For this reason, there is no possibility that the reactive gas, the separation gas, and the cleaning gas are mixed in the vacuum chamber 10.

Because it is necessary to secure the space for the circulatory movement of the substrate mounting part 5 in the vacuum chamber 10, the partition plate 17 cannot be formed in the regions of the substrate transporting device 4 outside the rotors 41 and 42. However, the processing region 13 to which the reactive gas is supplied, and the cleaning process part 8 are located between the substrate inlet part 11 and the substrate outlet part 14, and there appears to be no possibility that these gases flow into the regions of the substrate transporting device 4 outside the rotors 41 and 42 and are mixed there.

The exhaust ports 71 and 72 which are open to the ceiling part of the vacuum chamber 10, and the exhaust ports 76 which are open to the bottom of the vacuum chamber 10 are formed also in the regions of the substrate transporting device 4 outside the rotors 41 and 42, respectively. The gases in these regions flow towards these exhaust ports 71, 72, and 76, and the mixing of the reactive gas, the separation gas, and the cleaning gas is suppressed.

The purge gas is supplied to the upper part of the partition plate 17 of the circulatory transport path in the substrate transporting device 4. The amounts of the reactive gas, the separation gas, the cleaning gas, and the purge gas being supplied are respectively set up such that the pressure inside the circulatory transport path is higher than the pressure of the exterior of the circulatory transport path. For this reason, the gas flow which goes from the inside of the circulatory transport path to the exterior is formed, and the purge gas flows out of the gap between the substrate mounting part 5 and the vacuum chamber 10 and flows out of the gap between the substrate mounting part 5 and the spacer 53. Hence, it is possible to prevent the reactive gas, the separation gas, and the cleaning gas from entering the inside of the circulatory transport path, and there is no possibility that these gases are mixed in the vacuum chamber.

As described above, in this embodiment, the wafers W are mounted on the plurality of substrate mounting parts 5 arranged in the substrate transporting device 4 in the transporting direction, and the circulatory movement of the substrate transporting device 4 is performed. The first region S1 to which the first reactive gas is supplied and the second region S2 to which the second reactive gas is supplied are sequentially passed through the processing region 13 and the ALD (or MLD) process is performed. Hence, the film deposition process can be performed with good throughput. In the state where the substrate transporting device 4 is moved, the wafer W is delivered to the substrate mounting part 5 by the substrate delivery unit A1, and the wafer W is received from the substrate mounting part 5 by the substrate receiving unit A2. Thus, since the receiving and delivery of the wafer W are performed when the substrate mounting part 5 is moved and the film can be continuously formed on the wafer W, without stopping the substrate transporting device 4, it is possible to perform the film deposition process with high throughput.

The circulatory transport path of the substrate transporting device 4 includes the linear transport path. In the linear transport path, the parallel movement of the wafer W is performed, and all the points on the wafer W are moved at the same moving speed. Therefore, reactive gas molecules can be uniformly adsorbed by the wafer W by supplying the reactive gas uniformly from the reaction gas nozzles 61 and 62. For example, when performing the MLD process in the film deposition device in which a wafer is mounted in a circular mounting base, the mounting base is rotated and the reactive gases are alternately supplied to the wafer, the moving speed of the region of the wafer near the outer peripheral end of the mounting base is larger than the moving speed of the region of the wafer near the center of the mounting base. In this case, it is preferred that the reactive gas is supplied to the region of the wafer near the outer peripheral end of the mounting base at a high flow rate. If the flow rate of the reactive gas is determined to obtain a predetermined deposition rate in the region of the wafer near the outer peripheral end of the mounting base, a large amount of reactive gas will be supplied to the region of the wafer near the center of the mounting base. Wasteful consumption of the reactive gas may arise.

However, the film deposition device of the embodiment of the present disclosure is arranged such that supplying the reactive gas to the wafer at a different flow rate within the vacuum chamber is not needed. It is possible to avoid wasteful consumption of the reactive gas by using a comparatively simple method. As described above, the reactive gas is expensive, and reduction of the amount of the reactive gas used is advantageous for promoting reduction of the manufacturing cost.

Furthermore, in the substrate transporting device 4 of the present disclosure, the moving speed at the time of transport is equal to about 50 mm/sec, and the wafer W may be exposed to the reactive gas for a comparatively long time while the wafer is moved in the whole processing region 13. For this reason, it is not necessary to set up the flow rate of the reactive gas being supplied to a high level, and wasteful consumption of reactive gas can be avoided.

In this embodiment, while being exhausted from the exhaust port 71 and flowing through the exhaust path 73, the first reactive gas is collected by the collecting part 74 arranged in the exhaust path 73. On the other hand, the second reactive gas is exhausted from the exhaust port 72 and is supplied through the exhaust path 75. Therefore, the DER gas which is not used for the film deposition, but supplied, is collected by the collecting part 74 and the DER gas collected is not mixed with O₂ gas. For this reason, expensive DER gas can be re-used and the material cost of DER gas can be reduced.

In the above-described embodiment, the substrate transporting device 4 includes the circulatory transport path which is arranged around the horizontal rotating shaft in the vertical direction, and it is possible to perform the cleaning process for the substrate mounting part 5 under the circulatory transport path. For this reason, the cleaning process can be performed for the substrate mounting part 5 without increasing the installation area of the film deposition device 1. The cleaning process is performed for the substrate mounting part 5 which is moved along the circulatory transport path and the wafer W can always be delivered to the clean substrate mounting part 5. For this reason, occurrence of undesired particles can be suppressed and the yield can be improved.

In this example, in order to prevent mixing of the reactive gas and the cleaning gas, the size of the substrate mounting part 5 and the size of the vacuum chamber 10 are set up to provide a small gap between the substrate mounting part 5 and the vacuum chamber 10 when viewed from the upper part. The vacuum chamber 10 is formed to have the necessary minimum size, the exhausting time of the vacuum chamber 10 by the vacuum pump 7 can be reduced, the region to which the reactive gas is supplied can be decreased, and the amount of the reactive gas supplied can be reduced.

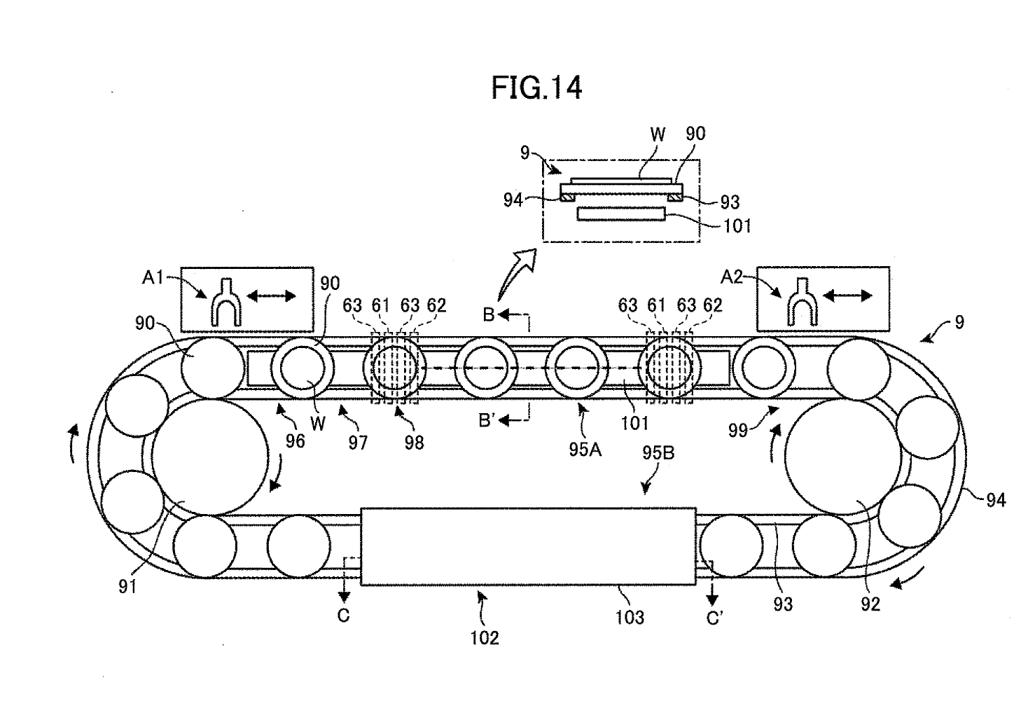

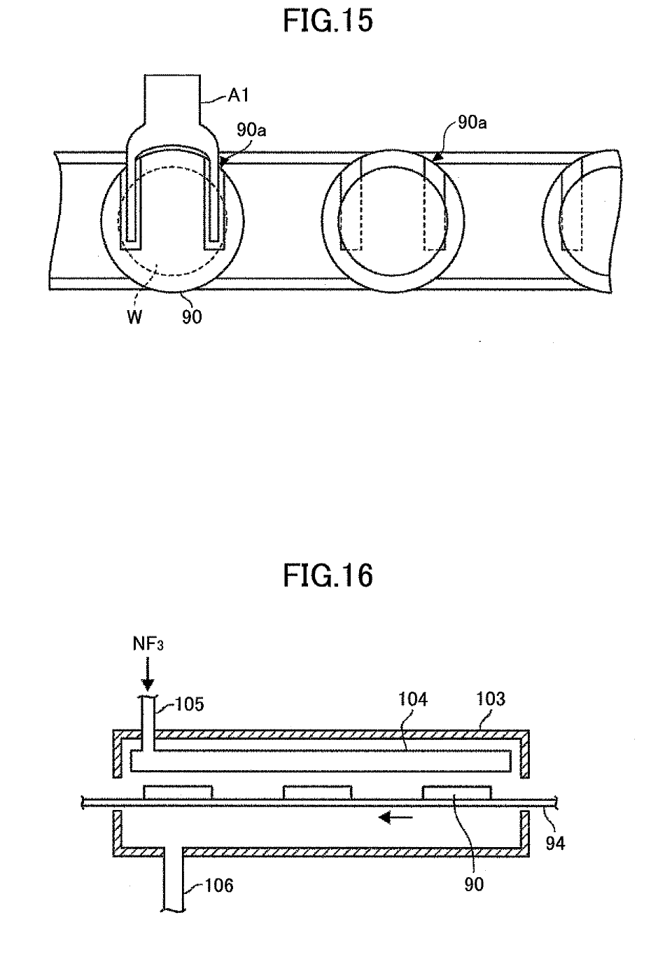

In another embodiment of the present disclosure, as illustrated in FIGS. 14-16, the substrate transporting device may be arranged so that the circulatory movement of the circulatory transport path is performed horizontally by rotors 91 and 92.

In this embodiment, each of the rotors 91 and 92 has a vertical rotating shaft. One of the rotors serves as a drive pulley and the other rotor serves as a driven pulley. A drive transmission belt 93 is wound around these rotors 91 and 92 and a belt member 94 is connected to the transmission belt 93, so that the transmission belt 93 and the belt member 94 perform the circulatory movement. In this embodiment, the circulatory transport path is arranged in this way.

In this embodiment, each of a plurality of substrate mounting parts 90 has a flat, circular shape. The plurality of substrate mounting parts 90 are disposed along the circulatory transport path. In each substrate mounting part 90, step parts 90a are formed for delivering/receiving a substrate between the substrate delivery unit A1 and the substrate mounting part 90 and between the substrate receiving unit A2 and the substrate mounting part 90. A substrate inlet part 96 is arranged at the upstream part of the linear transport path 95A in the transporting direction, and a substrate outlet part 99 is arranged at the downstream part of the linear transport path 95A in the transporting direction. A preheating region 97 and a processing region 98 are arranged between the substrate inlet part 96 and the substrate outlet part 99 sequentially along the transporting direction. In the processing region 98, the first reaction gas nozzle 61, the second reaction gas nozzle 62, and the separation gas nozzles 63 are arranged similar to the processing region 13 of the film deposition device in the previous embodiment. As illustrated in FIG. 14 (a cross-sectional view of the linear transport path 95A taken along the B-B′ line in FIG. 14), a heater unit 101 is disposed under the linear transport path in the substrate transporting device 9, and the heater unit 101 extends from the vicinity of the substrate inlet part 96 to the vicinity of the substrate outlet part 99.

In this embodiment, a cleaning process part 102 is disposed in a linear transport path 95B which is parallel with the linear transport path 95A in which the processing region 98 is arranged. As illustrated in FIG. 16 (which is a cross-sectional view of the cleaning process part 102 taken along the C-C′ line in FIG. 14), the cleaning process part 102 includes a processing container 103 which has two openings for permitting passage of the substrate mounting part 90. A plasma generating part 104 for supplying the cleaning gas in the plasma state to the surface of the substrate mounting part 90 is arranged in the inside of the processing container 103. A gas supplying part 105 for supplying NF₃ gas (which is the cleaning gas) to the plasma generating part 104 is arranged at the upper part of the processing container 103. An exhaust path 106 for exhausting the gas inside the processing container 103 is connected to the bottom of the processing container 103.

After the wafer W from the substrate mounting part 90 in the substrate outlet part 99 is received by the substrate receiving unit A2, the substrate mounting part 90 passes through the cleaning process part 102 during the circulatory movement of the substrate mounting part 90 from the substrate outlet part 99 to the substrate inlet part 96. In the cleaning process part 102, the surface of the substrate mounting part 90 is exposed to the cleaning gas in the plasma state, and the surface of the substrate mounting part 90 is cleaned.

In this embodiment, the wafer W is transported along the circulatory transport path which includes the linear transport path, and the gas supplying cycle is performed so that the first reactive gas and the second reactive gas are sequentially supplied to the wafer W. Hence, the film deposition process can be performed with good throughput. The wafer W is delivered/received between the substrate mounting part 90 and the substrate transporting device 9 without stopping the substrate transporting device 9, and the film deposition process can be performed continuously with high throughput.

The substrate mounting part 90 in the processing region 98 is transported along the linear transport path and the moving speed in the surface of the wafer W during the transport is the same. For this reason, it is not necessary to supply a large amount of reactive gas to the region of the wafer W in which the moving speed is small according to the region of the wafer W in which the moving speed is large, and wasteful consumption of reactive gas can be avoided.

In the above-described embodiment, DER gas is used as the first reactive gas and O₂ gas is used as the second reactive gas so that a Ru film is formed. Alternatively, in another embodiment, TiCl₄ gas may be used as the first reactive gas and NH₃ gas may be used as the second reactive gas so that a TiN film may be formed.

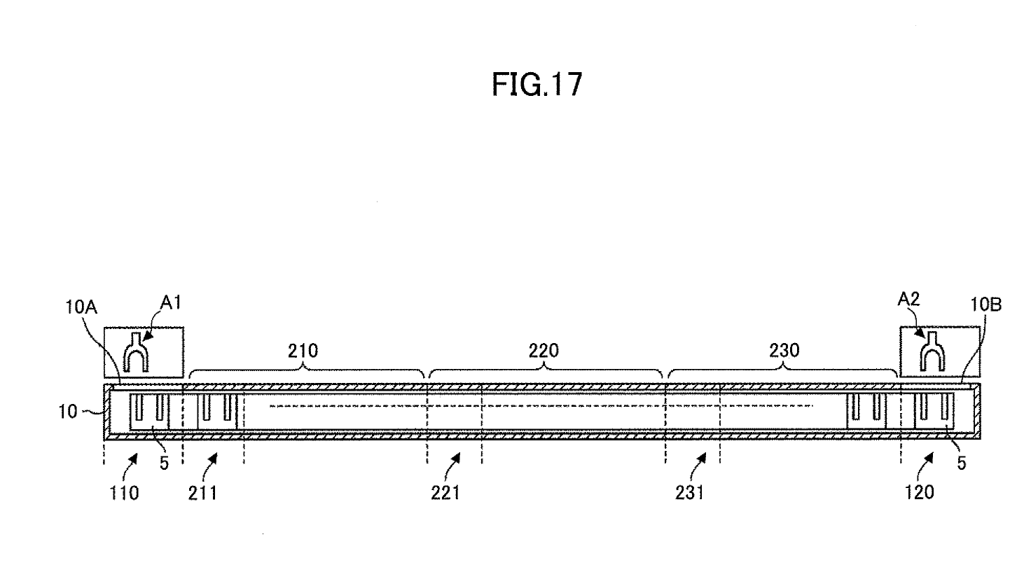

Alternatively, in another embodiment, as illustrated in FIG. 17, the length of the linear transport path in the circulatory transport path may be increased and a compound film deposition process may be performed. In the example of FIG. 17, the three processing regions 210, 220, and 230 are arranged between the substrate inlet part 110 and the substrate outlet part 120, and the preheating regions 211, 221, and 231 are arranged in the upstream positions of the processing regions 210, 220, and 230, respectively. In each of the processing regions 210, 220, and 230, the first and second reaction gas nozzles 61 and 62, and the separation gas nozzles 63 may be arranged similar to the above-described embodiment. However, in each processing region, different reactive gases are supplied to the first reaction gas nozzle 61 and the second reaction gas nozzle 62.

Specifically, in the example of FIG. 17, DER gas is used as the first reactive gas and O₂ gas is used as the second reactive gas in the first processing region 210, so that a Ru lower electrode is formed. In the second processing region 220, Sr[C₅(CH₃)₅]₂ gas is used as the first reactive gas, Ti[OCH(CH₃)₂]₄ gas is used as the second reactive gas, and O₃ gas is used as the third reactive gas, so that a STO insulating layer is formed. In the third processing region 230, DER gas is used as the first reactive gas and O₂ gas is used as the second reactive gas so that a Ru upper electrode is formed.

Alternatively, in another embodiment, the first exhaust port 71 which is open to the region in which the first reaction gas nozzle 61 is disposed and the second exhaust port 72 which is open to the region in which the second reaction gas nozzle 62 is disposed may be arranged in the side wall of the vacuum chamber 10, rather than the ceiling part of the vacuum chamber 10, so that the gases within the vacuum chamber 10 may be exhausted from the side of the linear transport path.

Alternatively, in another embodiment, the first reactive gas supplying part, the second reactive gas supplying part, and the third reactive gas supplying part may be arranged in this order along the linear transport path, so that the three reactive gases may be sequentially supplied to the substrate mounting part (the wafer) which is transported in the linear transport path. In this case, the first reactive gas supplying part and the second reactive gas supplying part may be alternately arranged along the linear transport path.

Alternatively, a V belt, a flat belt, or a wire and chain may be used as the transmission belt, instead of the above-described timing belt. The shape of the substrate mounting part is not limited to that in the above-described embodiment. For example, the example illustrated in FIG. 1 may be arranged so that the substrate mounting parts 5 and the spacers 53 are formed into an integral member. Alternatively, a plate-like transport member may be arranged on the timing belts 44 and 45 and the substrate mounting parts 5 may be mounted on the transport member. Alternatively, a recess with a shape which is in conformity with the shape of the wafer W may be formed in the substrate mounting part 5, and the wafer W mounted in the recess may be transported. Alternatively, the delivery of the wafer W between the substrate mounting part and the substrate delivery unit and between the substrate mounting part and the substrate receiving unit may be performed using lifting pins.

Alternatively, the load lock chambers 24A and 24B may be arranged so that preheating of the wafer W may be performed therein. If the film forming temperature used in the film deposition process of concern is not so high, it is not necessary to provide the preheating region. In this case, the reaction gas nozzle and the separation gas nozzle may be arranged near the substrate inlet part, and the reactive gas and the separation gas may be supplied to the linear transport path. In a case in which the reaction gas nozzle and the separation gas nozzle are selectively used or the preheating region is provided according to the film deposition process, the size of the preheating region may be adjusted. Providing the cleaning process part is not mandatory. If the cleaning process part is not provided, the partition plate 17 and the supply of the purge gas are not needed.

The present disclosure is not limited to the above-described embodiments, and it is to be understood that variations and modifications may be made without departing from the scope of the present disclosure as claimed.

The present international application is based upon and claims the benefit of priority of the prior Japanese patent application No. 2008-248801, filed on Sep. 26, 2008, the contents of which are hereby incorporated by reference in their entirety.

1. A film deposition device in which at least two mutually reactive gases are sequentially supplied to a surface of a substrate in a vacuum chamber and the gas supplying cycle is repeated a number of times, so that a plurality of resultant layers are laminated on the substrate surface to form a thin film thereon, the film deposition device comprising:
a substrate transporting device arranged in the vacuum chamber to include a circulatory transport path in which a plurality of substrate mounting parts arranged in a row are transported in a circulatory manner, the circulatory transport path including a linear transport path in which the plurality of substrate mounting parts are transported linearly;
a first reactive gas supplying part arranged. along a transporting direction in which the plurality of substrate mounting parts are transported in the linear transport path, to supply a first reactive gas to the plurality of substrate mounting parts which are transported in the linear transport path;
a second reactive gas supplying part arranged alternately with the first reactive gas supplying part along the transporting direction, to supply a second reactive gas to the plurality of substrate mounting parts which are transported in the linear transport path;
a separation gas supplying part arranged to supply a separation gas to a space between the first reactive gas supplying part and the second reactive gas supplying part, to separate a first region to which the first reactive gas is supplied from a second region to which the second reactive gas is supplied;
an exhaust part arranged to exhaust the gases inside the vacuum chamber;
a heating part arranged to heat a substrate on each of the plurality of substrate mounting parts;
a substrate inlet part arranged on an upstream side of the linear transport path in the transporting direction so that a substrate is delivered by each of the plurality of the substrate mounting parts; and
a substrate outlet part arranged on a downstream side of the linear transport path in the transporting direction so that a substrate from each of the plurality of substrate mounting parts is received through the substrate outlet part.

2. The film deposition device according to claim 1, wherein the substrate transporting device includes a pair of transmission belts which are wound between a pair of rotors whose rotating shafts are parallel to each other, to form the circulatory transport path.

3. The film deposition device according to claim 2, further comprising a motor for making at least one side of a pair of the rotors rotate in order to carry out circulatory movement of the pair of transmission belts.

4. The film deposition device according to claim 2, wherein the plurality of substrate mounting parts are arranged in the pair of transmission belts.

5. The film deposition device according to claim 1, wherein the vacuum chamber includes an exhaust port for exhausting gas from a space between adjacent separation gas supplying regions in the separation gas supplying part.

6. The film deposition device according to claim 5, wherein the exhaust port is disposed above the linear transport path.

7. The film deposition device according to claim 1, wherein the circulatory transport path is arranged around a horizontal rotating shaft in a vertical direction.

8. The film deposition device according to claim 1, wherein the circulatory transport path is arranged around a vertical rotating shaft in a horizontal direction.

9. The film deposition device according to claim 1, wherein a preheating region for preheating a substrate is arranged in the circulatory transport path between the substrate inlet part and the region where the first reactive gas supplying part, the second reactive gas supplying part, and the separation gas supplying part are arranged.

10. The film deposition device according to claim 1, further comprising a control part which outputs a control signal to an external substrate delivery unit so that the external substrate delivery unit delivers a substrate to one of the moving substrate mounting parts in the substrate inlet part, the control part outputting a control signal to an external substrate receiving unit so that the external substrate receiving unit receives a substrate from another of the moving substrate mounting parts in the substrate outlet part.

11. The film deposition device according to claim 1, wherein each of the first reactive gas supplying part and the second reactive gas supplying part contains a gas nozzle which is disposed to perpendicularly intersect the linear transport path.

12. The film deposition device according to claim 1, further comprising a cleaning process part which supplies a cleaning gas to the substrate mounting part which is moved to the substrate inlet part from the substrate outlet part in the substrate transporting device in order to perform a cleaning process for the substrate mounting part transported by the substrate transporting device.

13. A substrate processing device comprising:
a vacuum transport chamber which contains a substrate transporting device inside the vacuum transport chamber;
the film deposition device according to claim 1 which is airtightly connected to the vacuum transport chamber; and
a load lock chamber which is airtightly connected to the vacuum transport chamber and arranged so that an internal pressure of the load lock chamber is switchable between a vacuum pressure and an atmospheric pressure.
